(19) United States
(12) Patent Application Publication
(10) Pub. No.: US 2005/0169075 A1
(43) Pub. Date: Aug. 4, 2005

(54) Source driver and source line driving method for driving a flat panel display

(75) Inventor: Hyun-Sang Park, Seongnam-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/030,831

(22) Filed: Jan. 8, 2005

(30) Foreign Application Priority Data
Jan. 29, 2004 (KR) 2004-5650

(51) Int. Cl. G11C 7/00

(52) U.S. Cl. 365/203

(57) ABSTRACT

A source driver and a source line driving method for driving a flat panel display are provided. The source driver controls bias voltages of buffers that provide buffering for R, G, and B color signals using input/output signals generated by the flat panel display, or controls precharge voltages or precharge voltage widths of the respective buffers for buffering the R, G, and B color signals using inner precharge control circuits. The driving abilities of the output pins of the source driver transmitting the R, G, and B color signals are independently controlled, and therefore, identical charge characteristics can be obtained by respective R, G, and B pixels having different loads.

### CROSS-REFERENCE TO RELATED APPLICATION

This application claims the benefit of Korean Patent Application No. 2004-5650, filed on Jan. 29, 2004, in the Korean Intellectual Property Office, the disclosure of which is incorporated herein in its entirety by reference.

### TECHNICAL FIELD

The present invention generally relates to flat panel displays, and more particularly, to a source driver for driving a source line of a flat panel display.

### DESCRIPTION OF THE RELATED ART

Flat panel displays employ different technologies including Thin Film Transistor (TFT), Liquid Crystal Displays (LCD), organic Electro Luminescence (EL), a Super Twisted Nematic (STN)-LCD, Plasma Display Panel (PDP), etc.

FIG. 1 is a block diagram of a conventional TFT-LCD panel and peripheral circuits. An LCD panel 110 includes an upper panel and a lower panel, and a plurality of electrodes producing an electric field (see FIG. 5). Polarizing plates are attached to the upper panel and the lower panel to polarize light, and a liquid crystal layer is interposed between the upper panel and the lower panel. The brightness level in the TFT-LCD 100 is controlled by applying a grey voltage to the electrodes to rearrange the liquid crystal molecules.

The lower panel of the LCD 110 panel includes a plurality of switching elements such as TFTs that are connected to the electrodes to switch on and off the voltages applied to the electrodes. The brightness is controlled in pixels by the switching elements such as TFTs. The three colors, red R, green G, and blue B, are displayed by the pixels, which have a color filter arrangement shown in FIG. 2.

The TFT-LCD 100 includes a driving circuit block in which the gate drivers 120 that drive a plurality of gate lines are arranged along one edge of the LCD panel 110. The source drivers 130 that drive a plurality of source lines are arranged along an adjacent edge of the LCD panel 110, and a controller block (not shown) controls the driving circuit block such that the gate drivers 120 and the source driver 130 apply a grey voltage to the electrodes via switching elements. Generally, the controller block is disposed outside of the LCD panel 110. The driving circuit block is generally disposed outside of the LCD panel 110, but in the case of a Chip-On-Glass (COG) display, the driving circuit block may be disposed in the LCD panel 110.

FIG. 3 is a block diagram of a conventional source driver. Referring to FIG. 3, a conventional source driver 130 includes buffers 131 and Digital-to-Analog Converters (DACs) 132. The DACs 132 convert the R, G, or B digital data having predetermined grey values, inputted from the controller block, into analog image signals of corresponding grey voltages, and then outputs the analog signals.

The DAC 132 outputs analog image signals, which are buffered by the buffer 131 before being output to the source line. The buffers 131 can be Operational Amplifier (OP Amp) type analog circuits formed of a plurality of metal-oxide-semiconductor field effect transistors (MOSFETs). The OP Amp increases current driving ability using a predetermined bias voltage BIAS. The image signals are output from the buffer 131, and quickly charge the source line of the LCD panel 110 and the corresponding pixels. The pixel receiving the image signal rearranges the liquid crystal molecules in proportion to the corresponding grey voltage. Thus, the brightness of the LCD panel 110 is controlled.

FIGS. 4A through 4C are diagrams illustrating conventional pixel configuration. If the LCD 110 has a large-size and a high resolution, then a R, G, B, and W pixel configuration shown in FIG. 4A can be used, with the white pixels being used to improve the brightness. Conventionally, various pixel configurations emphasizing specific colors such as those shown in FIG. 4B and FIG. 4C are used, considering the color recognition variations between the individual conical cells.

The size of each pixel is changed according to the changes in the pixel configuration. The load of each pixel depends on the thickness of a Photo Resist (PR) forming a color filter, R, G or B, as shown in FIG. 5. A variance in the thickness of the PR between pixels exists in the general pixel configuration of FIG. 2. When the image signal is applied to a pixel by the source driver 130, and if each pixel has a different load, then there is a change in the charge characteristics of color signals having identical grey voltages. Therefore, pixels that were designed to show identical brightness may not provide color uniformity.

### SUMMARY OF THE INVENTION

One aspect of the invention provides a source driver for driving a flat panel display, in which the driving abilities of output pins transmitting color signals R, G, and B can be independently controlled such that identical charge characteristics are obtained by the respective R, G, and B pixels having different loads.

Another aspect of the invention also provides a technique of driving a source line of a flat panel display, in which identical charge characteristics are obtained by the respective R, G, and B pixels having different loads.

According to another aspect of the present invention, there is provided a source driver for driving a flat panel display that includes a plurality of DACs for converting the first, second, and third digital color signals which vary according to grey values, into analog image signals and outputting the analog image signals; a first buffer for buffering and outputting the analog image signal into which the first color signal is converted using a first bias voltage; a second buffer for buffering and outputting the analog image signal and in which the second color signal is converted using a second bias voltage; and a third buffer for buffering and outputting the analog image signal in which the third color signal is converted using a third bias voltage.

According to another aspect of the present invention, there is provided a source driver for driving a flat panel display that includes a plurality of precharge control circuits that combine the first, second, and third precharge signals having predetermined pulse widths with the first, second, and third digital color signals which vary according to grey values and hold the first, second, and third color signals using precharge grey values during the predetermined pulse widths.

The source driver further includes a plurality of level shifters for increasing the voltage levels of the first, second, and third color signals combined with the precharge grey values, to predetermined levels; a plurality of DACs for converting the first, second, and third color signals into analog image signals and outputting the analog image signals; and a plurality of buffers for buffering and outputting the analog image signals and in which the level-increased first, second, and third color signals are converted.

According to yet another aspect of the present invention, there is provided a source driver for driving a flat panel display that includes a first precharge control circuit for generating a first precharge signal in response to a precharge control signal, and combining a first digital color signal which varies according to a grey value associated with the first precharge signal, and holding the first color signal on a first precharge grey value during a predetermined pulse width.

The source driver further includes a second precharge control circuit for generating a second precharge signal in response to the precharge control signal, combining a second digital color signal which can vary according to the grey value associated with the second precharge signal, and holding the second color signal on a second precharge grey value during the predetermined pulse.

The source driver further includes a third precharge control circuit for generating a third precharge signal in response to the precharge control signal, combining a third digital color signal that changes according to the grey value with the third precharge signal, and holding the third color signal at a third precharge grey value during the predetermined pulse width; a plurality of level shifters increasing voltage levels of the first, second, and third color signals combined with the precharge grey values to predetermined levels; a plurality of DACs for converting the respective level-increased first, second, and third color signals into analog image signals and outputting the analog image signals; and a plurality of buffers for buffering and outputting the analog image signals into which the level-increased first, second, and third color signals are converted.

According to yet another aspect of the present invention, there is provided a source line driving technique for driving a flat panel display that includes the operations of converting the first, second, and third digital color signals which vary according to grey values into analog image signals buffering the analog image signals into which the first color signal is converted using a first bias voltage; buffering the analog image signals into which the second color signal is converted using a second bias voltage; and buffering the analog image signals into which the third color signal is converted using a third bias voltage.

According to a further aspect of the present invention, there is provided a source line driving technique for driving a flat panel display that includes the operations of combining the first, second, and third digital color signals which vary according to the grey value with the first, second, and third precharge signals having predetermined pulse widths; holding the respective first, second, and third color signals on precharge grey values during the predetermined pulse widths; increasing the voltage levels of the first, second, and third color signals combined with the precharge grey values to predetermined levels; converting the level-increased first, second, and third color signals into analog image signals; and buffering the analog image signals into which the level-increased first, second, and third color signals are converted.

According to another aspect of the present invention, there is provided a source line driving technique for driving a flat panel display that includes the operations of: generating a first precharge signal in response to a precharge control signal; combining a first digital color signal which can vary according to the grey value associated with the first precharge signal; outputting the first color signal held on a first precharge grey value during a predetermined pulse width; generating a second precharge signal in response to the precharge control signal; combining a second digital color signal which can vary according to the grey value associated with the second precharge signal during the predetermined pulse; outputting the second color signal held at a second precharge grey value; generating a third precharge signal using the precharge control signal; combining a third digital color signal changed according to the grey value with the third precharge signal; outputting the third color signal held on a third precharge grey value during the predetermined pulse width; increasing the voltage levels of the first, second, and third color signals combined with the precharge grey values; converting the level-increased first, second, and third color signals into analog image signals; and buffering the analog image signals into which the level-increased first, second, and third color signals are converted.

### BRIEF DESCRIPTION OF THE DRAWINGS

The exemplary embodiments of the present invention are described with reference to the accompanying drawings, of which:

FIG. 1 is a block diagram of a general Thin Film Transistor (TFT)-Liquid Crystal Display (LCD) panel and peripheral circuits thereof;

FIG. 2 is a diagram illustrating a general pixel configuration;

FIG. 3 is a block diagram of a conventional source driver;

FIGS. 4A through 4C are diagrams illustrating general pixel configurations;

FIG. 5 is a schematic diagram of an upper panel and a lower panel of the general TFT-LCD panel;

FIG. 6 is a block diagram of a source driver according to an exemplary embodiment of the present invention;

FIG. 7 is a block diagram of a source driver according to another exemplary embodiment of the present invention;

FIG. 8 is a timing diagram illustrating the operation of the source driver of FIG. 7;

FIG. 9 is a block diagram of a source driver according to another embodiment of the present invention; and

FIG. 10 is a timing diagram illustrating the operation of the source driver of FIG. 9.

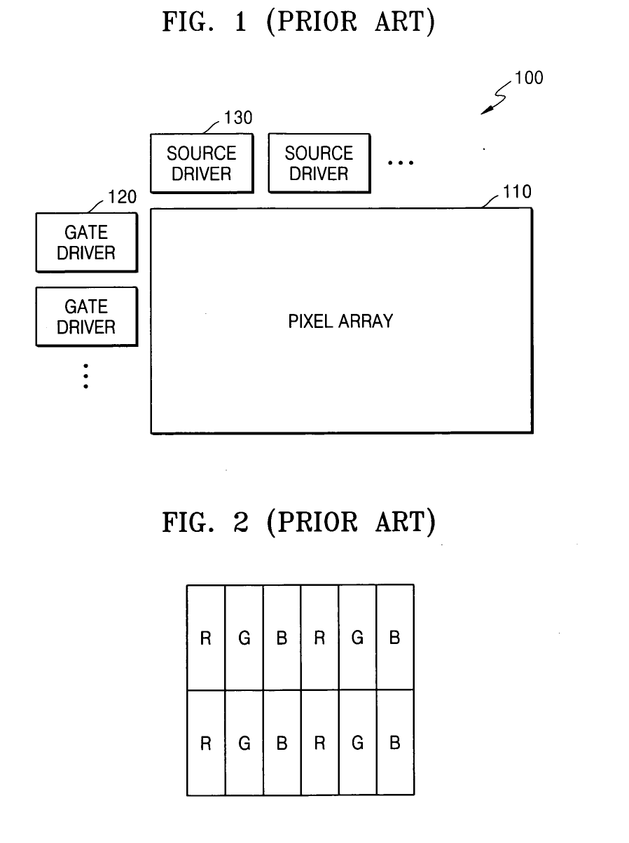

### DETAILED DESCRIPTION OF THE EXEMPLARY EMBODIMENTS

Exemplary embodiments of the present invention will be described with reference to the appended drawings.

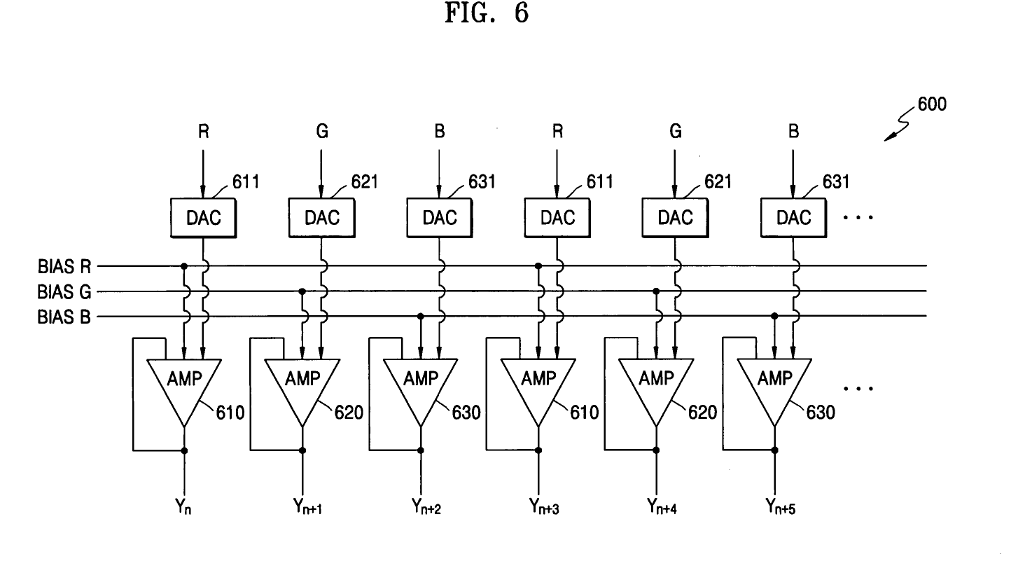

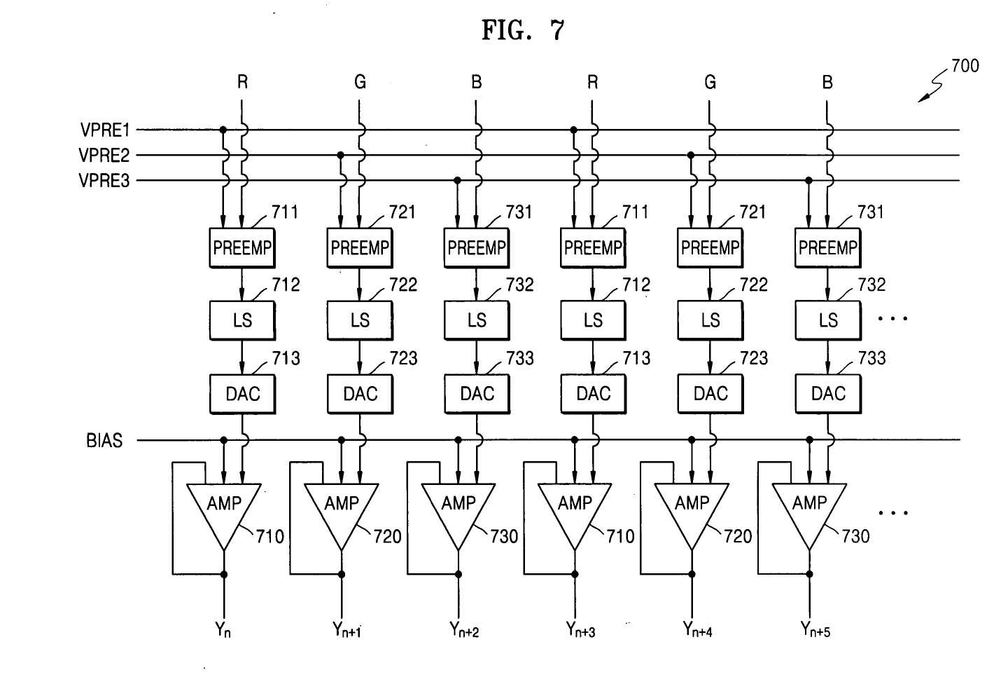

FIG. 6 is a block diagram of a source driver 600 according to an exemplary embodiment of the present invention. Referring to FIG. 6, the source driver 600 includes a plurality of Digital to Analog Converters (DACs) 611, 621 and 631 and a plurality of buffers 610, 620 and 630. The number of the DACs 611, 621 and 631 and the buffers 610, 620, and 630 included is sufficient to provide a designated resolution of an LCD panel 110. The DACs 611, 621, and 631 respectively convert the first, second, and third digital color signals R, G, and B according to grey values into analog image signals, and output the analog image signals. The buffers 610, 620, and 630 respectively receive, buffer and output the analog signals output from the DACs 611, 621, and 631. Buffered image signals Yn, Yn+1, Yn+2, . . . are output to source lines via package pins.

The buffers 610, 620 and 630 are Operation Amplifiers (OP Amps) that can be made of numerous Metal-Oxide-Semiconductor Field Effect Transistors (MOSFETs). The OP Amp circuits increase current driving ability using bias voltages BIASR, BIASG, and BIASB. The image signals Yn, Yn+1, Yn+2, . . . are output from the buffers 610, 620 and 630 and quickly charge the source lines and the corresponding pixels of the LCD panel 110. The pixels that receive the image signal rearrange liquid crystal molecules in proportion to the corresponding grey voltages. In this way, the brightness of the LCD panel 110 is controlled.

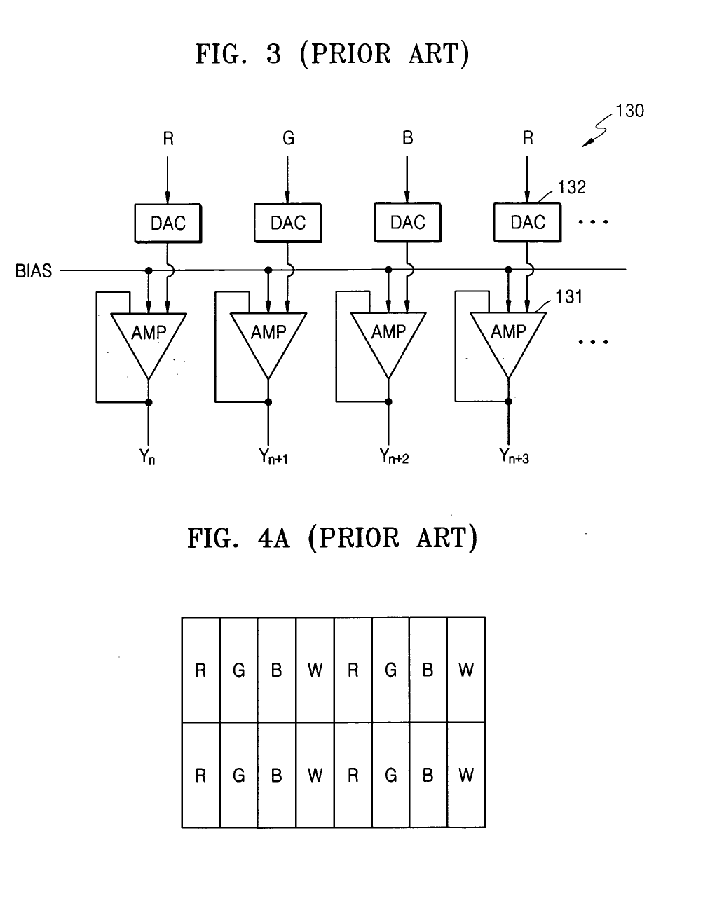

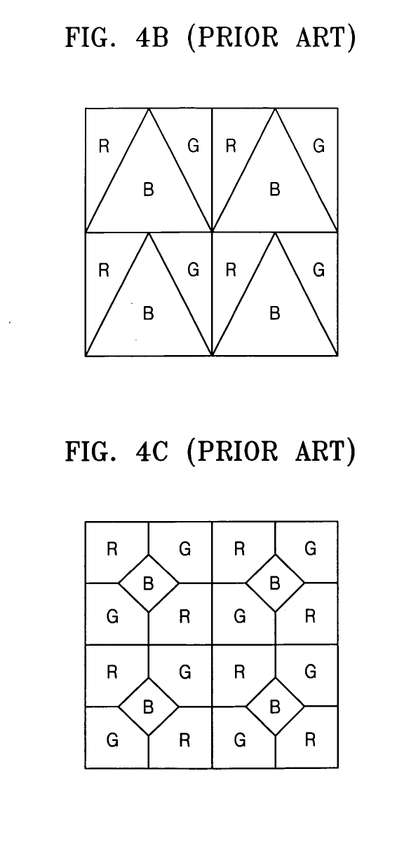

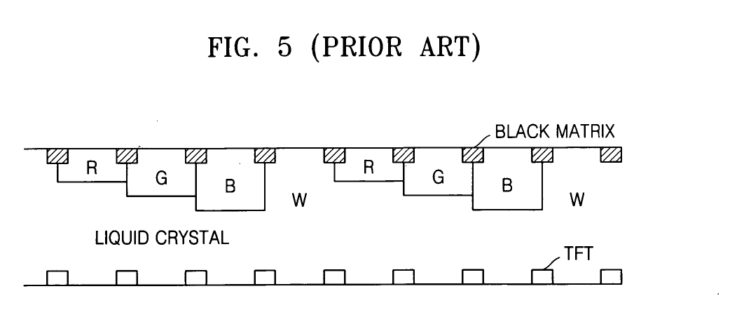

The source driver 600 in which the buffers 610, 620 and 630 use bias voltages BIASR, BIASG, and BIASB, which are different from each other, is different from a conventional source driver 130 in which one predetermined bias voltage BIAS is used, as shown in FIG. 3. Since the R, G, B pixels have different loads in the LCD panel 110 that includes a pixel arrangement such as one of those shown in FIGS. 4A through 4C, there is a need to compensate for different charge characteristics between the pixels. This compensation of charge characteristics can be achieved with the source driver 600.

For example, first buffers 610, second buffers 620, and third buffers 630 buffer the first, second, and third color signals R, G, and B. Using the first bias voltage BIASR, the first buffers 610 buffer and output analog image signals into which the first color signals R have been converted by the first DAC 611. Using the second bias voltage BIASG, the second buffers 620 buffer and output the analog image signals into which the second color signals G have been converted by the second DAC 621. Using the third bias voltage BIASB, the third buffers 630 buffer and output analog image signals into which the third color signals B are converted at the third DAC 631.

The bias voltages BIASR, BIASG, and BIASB can be generated in the source driver 600 or can be applied from the outside via the package pin of the source driver 600 for a convenient set up. Accordingly, if the bias voltages BIASR, BIASG, and BIASB are different, driving abilities of the OP Amp circuits formed by the buffers 610, 620, and 630 are different.

The driving ability of the output pins transmitting the respective color signals R, G and B, produced by the source driver 600 can be separately controlled. An output pin corresponding to a pixel having a large load may drive a large current, and an output pin corresponding to a pixel having a small load may have a small current driving ability. Thus, the R, G, and B pixels, having different loads, can have the same charge characteristics, and color reproducibility is improved. Also, the driving characteristics of the source driver 600 are optimized to decrease the electric power consumption.

Other source drivers in which the driving ability of the output pins can be separately controlled are described next. FIG. 7 is a block diagram of a source driver 700 according to another exemplary embodiment of the present invention. The source driver 700 includes a plurality of precharge control circuits 711, 721, and 731, a plurality of level shifters 712, 722, and 732, a plurality of DACs 713, 723, and 733, and a plurality of buffers 710, 720, and 730. The number of the precharge control circuits 711, 721, and 731, the level shifters 712, 722, and 732, the DACs 713, 723, and 733, and the buffers 710, 720, and 730 is sufficient to provide a designated resolution of the LCD panel 110.

The precharge control circuits 711, 721, and 731 hold the respective first, second, and third color signals R, G, and B on the precharge grey values for a predetermined pulse period by combining the first, second, and third precharge signals VPRE1, VPRE2 and VPRE3 having the predetermined widths to the respective first, second, and third color signals R, G and B, which vary according to the grey values.

The first, second and third precharge signals VPRE1, VPRE2, and VPRE3 are separately generated and input to the source driver 700 externally via the package input pins of the source driver 700. The precharge grey value has a predetermined value that may be a as large as possible value for signals output from the buffers 710, 720, and 730 to quickly charge the source line. For example, the precharge grey value for a pixel capable of 256 grey shades is 256.

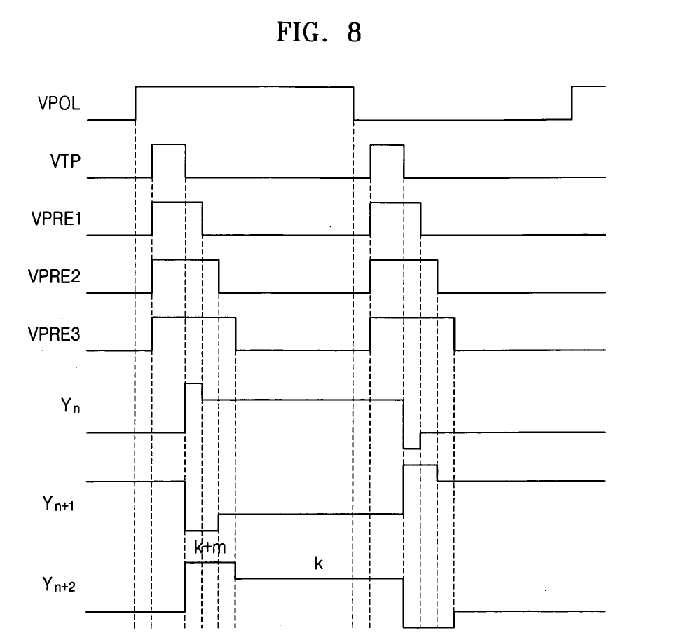

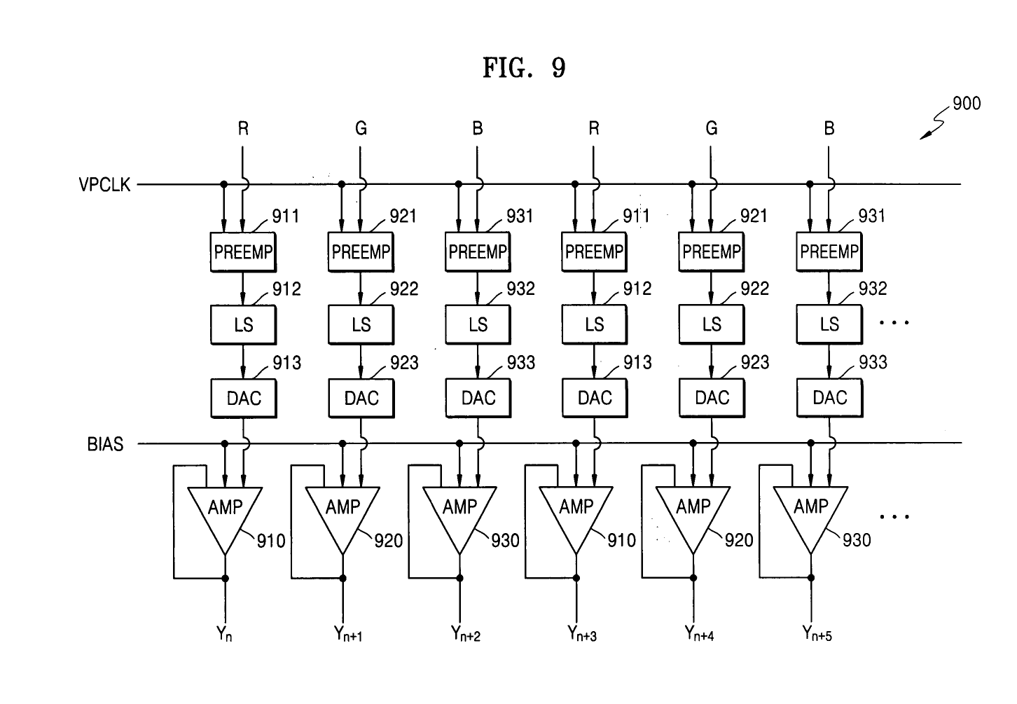

Operation of the precharge control circuits 711, 721, and 731 will be described with reference to FIG. 8. The level shifters 712, 722, and 732 respectively increase voltage levels of the first, second, and third color signals R, G, and B with which the precharge grey value has been combined. The voltages are increased to a peak-to-peak voltage level needed for the conversion operations of the DACs 713, 723, and 733.

The DACs 713, 723, and 733 respectively convert the first, second, and third color signals R, G, and B having increased levels into analog image signals, and output the analog image signals. The buffers 710, 720, and 730 respectively buffer and output the analog image signals into which the first, second, and third color signals R, G, and B have been converted. The buffers 710, 720, and 730 buffer the analog image signals using a predetermined bias voltage BIAS that is generated and applied internally or externally via the package pin of the source driver 700.

FIG. 8 is a timing diagram illustrating the operation of the source driver 700 of FIG. 7. Referring to FIGS. 7 and 8, the first precharge control circuit 711 combines the first precharge signal VPRE1 having the first pulse width and the first color signal R, which is a digital signal having a K grey value, and holds the first color signal R on a precharge grey value (k+m) during the first pulse width.

The second precharge control circuit 721 combines the second precharge signal VPRE2 having the second pulse width and the second color signal G, which is a digital signal having a K grey value, and holds the second color signal G on the precharge grey value (k+m) during the second pulse width.

The third precharge control circuit 731 combines the third precharge signal VPRE3 having the third pulse width and the third color signal B, which is a digital signal having a K grey value, and holds the third color signal B on the precharge grey value (k+m) during the third pulse width. Here, the grey value of the first, second, and third color signals R, G, and B is k, but, as is known to those skilled in the art, the first, second, and third color signals R, G, and B have different grey values for each horizontal period (scan period) when the images are displayed.

Referring to FIG. 8, the pulse widths of the respective first, second, and third precharge signals VPRE1, VPRE2, and VPRE3 are different from each other. Accordingly, digital signals in which the first, second, and third precharge signals VPRE1, VPRE2, and VPRE3 are combined with the first, second, and third color signals R, G, and B, respectively, are output from the precharge control circuits 711, 721, and 731. The digital signals hold a precharge grey value (k+m) during each pulse width are outputted via the level shifters 712, 722, and 732, the DACs 713, 723, and 733, and the buffers 710, 720, and 730 to the source lines. Image signals Yn, Yn+1, Yn+2, . . . are output from the buffers 710, 720, and 730 with the output waveforms as shown in FIG. 8.

Referring to FIG. 8, the pulse width of the first precharge signal VPRE1 is less than the pulse width of the second precharge signal VPRE2, and the pulse width of the second precharge signal VPRE2 is less than the pulse width of the third precharge signal VPRE3. Here, the pulse width of the precharge signals VPRE1, VPRE2, and VPRE3 is a period when the precharge signals VPRE1, VPRE2, and VPRE3 are in logic high states within each horizontal cycle. The DACs 713, 723, and 733 start the digital-to-analog conversions when the precharge signals VPRE1, VPRE2, and VPRE3 are in a high logic state in response to a predetermined synchronizing signal VTP.

Thus, during an initial period of digital-to-analog conversion (a precharge period), the image signal Yn+1 output from the second buffer 720 holds the precharge grey value (k+m) longer than the image signal Yn that was outputted from the first buffer 710, the image signal Yn+2 outputted from the third buffer 730 holds the precharge grey value (k+m) longer than the image signal Yn+1 output from the second buffer 720. As is known by those skilled in the art, the buffers 710, 720, and 730 can provide the image signals Yn, Yn+1, Yn+2, . . . as a form of a column inversion according to a polarity indicator signal VPOL.

To prevent deterioration of the material characteristics of the liquid crystal material injected in the LCD panel 110 the buffers 710, 720, and 730 alternately provide positive polarity image signals Yn, Yn+1, Yn+2, . . . having voltages higher than a common voltage and negative polarity image signals Yn, Yn+1, Yn+2, . . . having voltages lower than the common voltage at each horizontal period. Although the signals and elements for realizing display methods such as a line inversion method or a dot inversion method are not shown in FIG. 7, the source driver 700 can employ these known methods.

FIG. 9 is a block diagram of a source driver 900 according to another exemplary embodiment of the present invention. The source driver 900 includes a plurality of precharge control circuits 911, 921, and 931, a plurality of level shifters 912, 922, and 932, a plurality of DACs 913, 923, and 933, and a plurality of buffers 910, 920, and 930. The number of the precharge control circuits 911, 921, and 931, the level shifters 912, 922, and 932, the DACs 913, 923, and 933, and the buffers 910, 920, and 930 is sufficient to provide a designated resolution of the LCD panel 110.

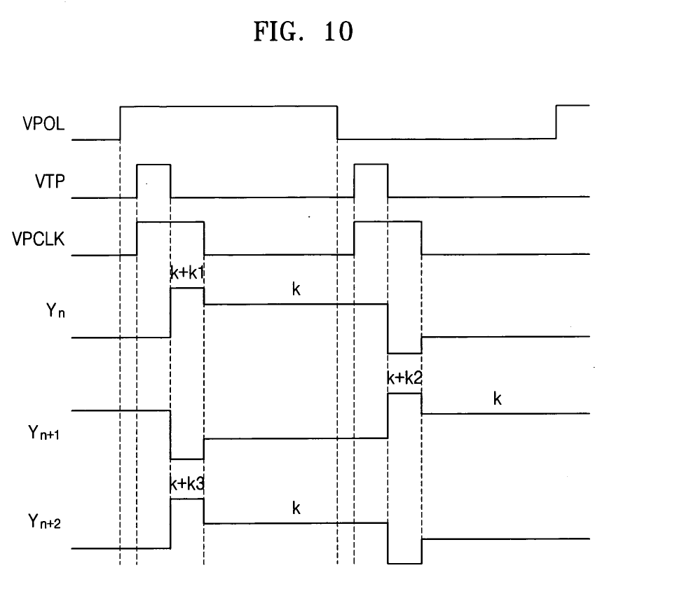

While the precharge control circuits 711, 721, and 731 of FIG. 7 combine the precharge signals VPRE1, VPRE2, and VPRE3, which have different pulse widths, the precharge control circuits 911, 921, and 931 combine and output precharge signals having voltage levels different from each other using a precharge control signal VPCLK (refer to FIG. 10).

Respective precharge signals corresponding to the first, second, and third color signals R, G, and B have different voltages, and thus the precharge grey values of the first, second, and third color signals R, G, and B are different from each other, while the pulse widths of the precharge signals are the same. The precharge control signal VPCLK is inputted externally via a package input pin of the source driver 900.

The operation of the precharge control circuits 911, 921, and 931 will be described with reference to FIG. 10. The level shifters 912, 922, and 932 increase the voltage level of each of the first, second, and third color signals R, G, and B combined with the precharge grey value to a predetermined level. The voltage is increased to the peak-to-peak voltage level needed for the DACs 913, 923, and 933 to perform the digital-to-analog conversion.

The DACs 913, 923, and 933 respectively convert into analog signals the first, second, and third color signals R, G, and B with the increased levels, and output the analog signals. The buffers 910, 920, and 930 buffer the analog signals into which the respective first, second, and third color signals R, G, and B with the increased levels are converted, and output the buffered analog signals. The buffers 910, 920, and 930 buffer the analog signals using the predetermined bias voltage BIAS, and the bias voltage BIAS may be generated and applied internally or may be applied externally via the package pin of the source driver 900.

FIG. 10 is a timing diagram illustrating the operation of the source driver 900 of FIG. 9. Referring to FIGS. 9 and 10, the first precharge control circuit 911 generates the precharge signal for the first color signal R in response to the precharge control signal VPCLK, and combines the first color signal R, which is a digital signal having a k grey value and the precharge signal for the first color signal R.

The precharge control circuit 911 outputs the first color signal R held at a first precharge grey value (k+k1), during a predetermined pulse width. The second precharge control circuit 921 generates the precharge signal for the second color signal G in response to the precharge control signal VPCLK, and combines the second color signal G in a digital form having a k grey value and the precharge signal for the second color signal G.

The precharge control circuit 921 outputs the second color signal G held at a second precharge grey value (k+k2), during the predetermined pulse width. The third precharge control circuit 931 generates the precharge signal for the third color signal B in response to the precharge control signal VPCLK, and combines the third color signal B in a digital form having the k grey value and the precharge signal for the third color signal B.

The precharge control circuit 931 outputs the third color signal B held at a third precharge grey value (k+k3), during the predetermined pulse width. The grey value of the first, second, and third color signals R, G, and B is k, as it is known to those skilled in the art, the first, second, and third color signals R, G, and B have different grey value depending on the horizontal period of displaying of the LCD panel 110.

As described above, the respective precharge signals for the first, second, and third color signals R, G, and B have different voltages, and therefore, the precharge grey values of the first, second, and third colors R, G, and B are different from each other. Accordingly, referring to FIG. 10, the precharge control circuits 911, 921, and 931 respectively combine the precharge signals for the first, second, and third color signals R, G, and B with the first, second, and third color signals R, G, and B to form digital signals.

The digital signals are kept at the precharge grey values k+k1, k+k2, and k+k3, which are different from each other, during the same pulse width and are output to the source lines via the level shifters 912, 922, and 932, the DACs 913, 923, and 933, and the buffers 910, 920, and 930.

Image signals Yn, Yn+1, Yn+2, . . . are output from the buffers 910, 920, and 930 with the output waveforms as shown in FIG. 10. Referring to FIG. 10, since the pulse width of the precharge signal for the first color signal R, the pulse width of the precharge signal for the second color signal G, and the pulse width of the precharge signal for the third color signal B are all the same. Further, the precharge periods of the image signals Yn, Yn+1, Yn+2, . . . are all the same too, as shown in FIG. 10.

The pulse width of each of the precharge signals for the first, second, and third color signals R, G, and B is a period when the precharge signals are in the logic high states within each horizontal period. The DACs 913, 923, and 933 start digital-to-analog conversions when the precharge signals for the first, second, and third color signals R, G, and B are in a high logic state in response to the predetermined synchronizing signal VTP.

Thus, during the initial period of the digital-to-analog conversion (the precharge period), the image signal Yn+1 output from the second buffer 920 can hold the precharge grey value k+k2 having a higher voltage level than the image signal Yn output from the first buffer 910, and the image signal Yn+2 output from the third buffer 930 can hold the precharge grey value k+k3 having a higher voltage level than the image signal Yn+1 output from the second buffer 920. As is known to those skilled in the art, the buffers 910, 920, and 930 can produce the image signals Yn, Yn+1, Yn+2, . . . in the form of a column inversion in response to the polarity indicator signal VPOL.

Although signals and forming elements for realising display methods other than the column inversion such as the line inversion method or the dot inversion method, are not shown in FIG. 9, the source driver 900 can be applied to all the techniques as described above in other exemplary embodiments of the invention.

As described above, according to at least one exemplary embodiment of the present invention, the source driver 600 driving the flat panel display can control the bias voltages BIASR, BIASG, and BIASB of the respective buffers 610, 620, and 630 for the color signals R, G, and B in response to the input/output signals generated by the flat panel display.

The source driver 600 can control the precharge voltage or the precharge width of the respective buffers for the color signals R, G, and B. Accordingly, the driving abilities of the respective output pins transmitting the color signals R, G, and B may be controlled separately, and the same charge characteristics may be applied to the respective R, G, and B pixels having different loads.

As described above, in the flat panel display having a non-uniform pixel configuration in which the R, G, B, and W pixels exist or areas between pixels are different, the source driver driving a flat panel display, according to an exemplary embodiment of the present invention, provides proper driving ability according to the load of a pixel. Therefore, a color reproduction difference caused by differences in characteristics such as transmittance and thickness of color filters are reduced thereby improving image quality. Also, the driving characteristics of the source driver are optimized to reduce power consumption.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A source driver in a flat panel display, comprising:
a plurality of Digital-to-Analog converters (DACs) for converting a first, a second, and a third digital color signal, each of which varies according to grey values, into analog image signals;
a first buffer for buffering and outputting the analog image signals into which the first color signal is converted using a first bias voltage;
a second buffer for buffering and outputting the analog image signals into which the second color signal is converted using a second bias voltage; and
a third buffer for buffering and outputting the analog image signals into which the third color signal is converted using a third bias voltage.

2. The source driver of claim 1, wherein the first, the second and the third bias voltages are generated and applied by the source driver.

3. The source driver of claim 1, wherein the first, the second and the third bias voltages are applied externally via a plurality of package pins of the source driver.

4. A source driver of claim 1, further comprising:
a plurality of precharge control circuits for combining a first, a second, and a third precharge signal, each of which having a predetermined pulse width, with the first, the second, and the third digital color signal, each of which varies according to grey values, and holding the first, second, and third color signals at precharge values during the predetermined pulse widths; and
a plurality of level shifters for increasing the voltage levels of the first, second, and third color signals to predetermined levels, wherein the color signals are combined with the precharge signals.

5. The source driver of claim 4, wherein the precharge grey values are values corresponding to a maximum grey level.

6. The source driver of claim 4, wherein the predetermined pulse widths of the first, second and third precharge signals are different from each other.

7. The source driver of claim 4, wherein the buffers provide buffering for the analog image signals using a predetermined bias voltage, and the predetermined bias voltage is generated and applied by the source driver or applied externally via a package pin of the source driver.

8. A source driver in a flat panel display, comprising:
a first precharge control circuit for generating a first precharge signal in response to a precharge control signal, combining a first digital color signal that varies according to grey value with the first precharge signal, and holding the first color signal on a first precharge grey value during a predetermined pulse width;
a second precharge control circuit for generating a second precharge signal in response to the precharge control signal, combining a second digital color signal that varies according to a grey value with the second precharge signal, and holding the second color signal at a second precharge grey value during the predetermined pulse width;
a third precharge control circuit for generating a third precharge signal in response to the precharge control signal, combining a third digital color signal that varies according to a grey value with the third precharge signal, and holding the third color signal on a third precharge grey value during the predetermined pulse width;
a plurality of level shifters for increasing the voltage levels of the first, second, and third color signals combined with the precharge grey values to predetermined levels;
a plurality of DACs for converting the level-increased first, second, and third color signals into analog image signals and outputting the analog image signals; and
a plurality of buffers for buffering and outputting the analog image signals into which the level-increased first, second, and third color signals are converted.

9. The source driver of claim 8, wherein the first, second, and third precharge signals have different voltages during the predetermined pulse width.

10. The source driver of claim 8, wherein the buffers that provide buffering use the predetermined bias voltage, and the predetermined bias voltage is generated and applied by the source driver or applied externally via a package pin of the source driver.

11. A source line driving method for a flat panel display, comprising the steps for:
converting a first, a second, and a third digital color signal each of which varies according to grey values into analog image signals;
buffering the analog image signals into which the first color signal is converted using a first bias voltage;
buffering the analog image signals into which the second color signal is converted using a second bias voltage; and
buffering the analog image signals into which the third color signal is converted using a third bias voltage.

12. A source line driving method for a flat panel display, comprising the steps for:
combining a first, a second and a third digital color signal, each of which varies according to a grey value, with a first, a second and a third precharge signal having predetermined pulse widths;
holding the first, second and third color signals on precharge grey values during the predetermined pulse widths;
increasing voltage levels of the first, second and third color signals combined with the precharge grey values to predetermined levels;
converting the level-increased first, second and third color signals into analog image signals; and
buffering the analog image signals into which the respective level-increased first, second, and third color signals are converted.

13. The method of claim 12, wherein the precharge grey values are values corresponding to a maximum grey level.

14. The method of claim 12, wherein the predetermined pulse widths of the first, second, and third precharge signals are different from each other.

15. A source line driving method of driving a flat panel display, comprising the operations of:
generating a first precharge signal in response to a precharge control signal;
combining a first digital color signal which varies according to a grey value with the first precharge signal;
outputting the first color signal held at a first precharge grey value during a predetermined pulse width;
generating a second precharge signal in response to the precharge control signal;
combining a second digital color signal that varies according to the grey value with the second precharge signal;
outputting the second color signal held at a second precharge grey value during the predetermined pulse width;
generating a third precharge signal using the precharge control signal;
combining a third digital color signal that varies according to the grey value with the third precharge signal;
outputting the third color signal held at a third precharge grey value during the predetermined pulse width;
increasing the voltage levels of the first, second, and third color signals combined with the precharge grey values;
converting the level-increased first, second, and third color signals into analog image signals; and
buffering the analog image signals into which the level-increased first, second, and third color signals are converted.

16. The method of claim 15, wherein the respective first, second, and third precharge signals have different voltages during the predetermined pulse width.
